(19) United States
(12) Patent Application Publication
(10) Pub. No.: US 2024/0170351 A1
(43) Pub. Date: May 23, 2024

(54) REDISTRIBUTION LAYERS IN A DIELECTRIC CAVITY TO ENABLE AN EMBEDDED COMPONENT

(71) Applicant: Intel Corporation, Santa Clara, CA (US)

(72) Inventors: Jeremy D. Ecton, Gilbert, AZ (US); Gang Duan, Chandler, AZ (US); Brandon Christian Marin, Gilbert, AZ (US); Suddhasattwa Nad, Chandler, AZ (US); Srinivas V. Pietambaram, Chandler, AZ (US)

(73) Assignee: Intel Corporation, Santa Clara, CA (US)

(21) Appl. No.: 17/992,010

(22) Filed: Nov. 22, 2022

(51) Int. Cl. H01L 23/13; H01L 21/48; H01L 23/00; H01L 23/15; H01L 23/498; H01L 23/538; H01L 25/16

(52) U.S. Cl. CPC H01L 23/13; H01L 21/4857; H01L 21/486; H01L 23/15; H01L 23/49822; H01L 23/49838; H01L 23/5381; H01L 23/5386; H01L 24/16; H01L 24/17; H01L 24/32; H01L 24/73; H01L 25/167; H01L 23/49833; H01L 23/5385; H01L 2224/1601; H01L 2224/16057; H01L 2224/1607; H01L 2224/16227; H01L 2224/16238; H01L 2224/1703; H01L 2224/17055; H01L 2224/32225; H01L 2224/73204; H01L 2224/73253; H01L 2924/1511; H01L 2924/15153; H01L 2924/15174; H01L 2924/15788

(57) ABSTRACT

Architectures and processes for redistribution layers in a dielectric cavity to enable an embedded component in semiconductor packaging. The architectures pattern redistribution layers (RDL) over a thick seed and remove dielectric material from the RDL conductive contacts to create the dielectric cavity. The architectures enable 2-sided connections for embedded components in the dielectric cavity with minimal disruption to existing process infrastructure. Such an approach can be used not only for integration of photonic devices, but also for any semiconductor packaging requiring dual sided connection within a dielectric cavity.

### BACKGROUND

High-speed signaling and telecommunication infrastructures rely heavily on optical signaling and drive a demand for sophisticated semiconductor packages that include embedded components. The integration of an embedded component to effectively connect with another die in a semiconductor package at a desired bandwidth can be technically challenging. Accordingly, continued improvements to semiconductor package architectures and methodologies that support high-speed and optical signaling are desired.

### BRIEF DESCRIPTION OF THE DRAWINGS

FIG. 1 illustrates an example semiconductor package that implements at least one embedded component, in accordance with various embodiments.

FIG. 2 provides simplified cross-sectional illustrations of a glass core patterned with thick seed and redistribution layers (RDL), in accordance with various embodiments.

FIG. 3 provides a simplified cross-sectional illustration of embodiments in FIG. 2 with additional RDL built up on upper and lower surfaces, in accordance with various embodiments.

FIG. 4 illustrates creating a dielectric cavity with exposed RDL in the dielectric layer of the upper surface, in accordance with various embodiments.

FIG. 5 illustrates the embodiment of FIG. 4, after a wet etch to remove the thick seed, in accordance with various embodiments.

FIGS. 6-7 are simplified illustrations depicting embodiments of an embedded component on the RDL in the dielectric cavity, in accordance with various embodiments.

FIGS. 8-9 are simplified illustrations depicting another methodology for creating the RDL in the dielectric cavity, in accordance with various embodiments.

FIGS. 10-11 illustrate an example method for manufacturing and implementing an interposer, in accordance with various embodiments.

FIG. 12 is a top view of a wafer and dies that may be included in a microelectronic assembly, in accordance with any of the embodiments disclosed herein.

FIG. 13 s a simplified cross-sectional side view showing an implementation of an integrated circuit on a die that may be included in various embodiments, in accordance with any of the embodiments disclosed herein.

FIG. 14 is a cross-sectional side view of a microelectronic assembly that may include any of the embodiments disclosed herein.

FIG. 15 is a block diagram of an example electrical device that may include any of the embodiments disclosed herein.

### DETAILED DESCRIPTION

The integration of electrical components and optical components in semiconductor packaging to meet the expectations of high-speed signaling often involves the technical challenge of embedding a component that is optical or electrical. Some non-limiting examples of optical components that may be embedded include photonic devices (integrated circuits (ICs), switches, light sources, waveguides, and detectors). A non-limiting example of an electrical component that may be embedded is a silicon bridge.

A proposed technical solution includes implementing an “open cavity architecture” that locates an embedded component in a dielectric cavity in a substrate package. However, this approach precipitates a new set of technical challenges, particularly for implementing any 2-sided connections (e.g., between an upper surface and a lower surface) for the embedded. In a non-limiting example, 2-sided connections can be needed for power delivery, connecting an embedded component on a first side (or lower surface) to a layer of conductive traces inside the cavity referred to as a cavity layer or cavity layer interconnect (CLI) and connecting the embedded component on a second side (or upper surface) to die interconnect routing to a different die in the package substrate (the die interconnect may also be referred to as first level interconnect (FLI)).

Embodiments described herein provide a technical solution to these technical challenges in the form of architectures and process flows that enable 2-sided connections for embedded components with minimal disruption to existing process infrastructure. Such an approach can be used not only for integration of photonic devices, but also for any architecture requiring dual sided connection within a cavity, for example, embedded silicon bridges. These concepts are developed in more detail below.

Example embodiments are hereinafter be described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

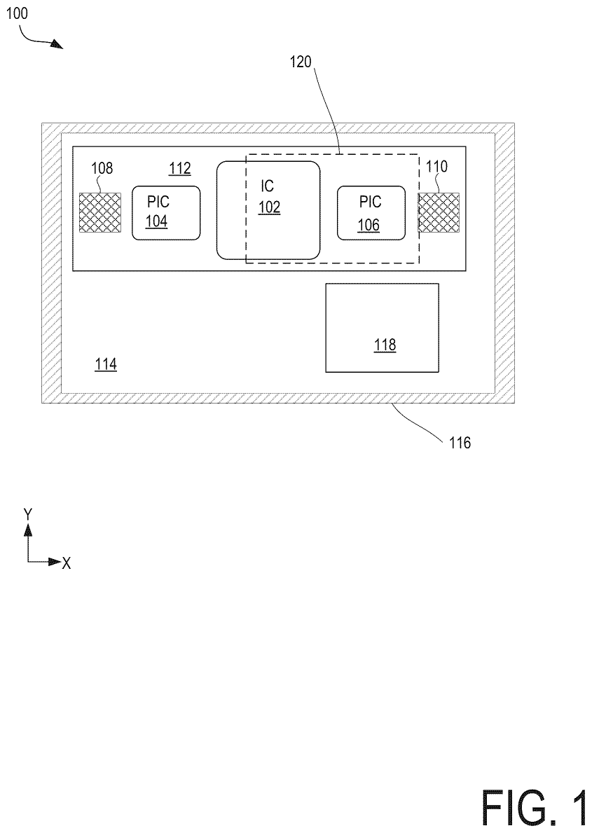

The non-limiting example in FIG. 1 is a semiconductor package 100 that integrates electrical and optical signaling and implements at least one embedded component. The semiconductor package 100 comprises an integrated circuit (IC) die 102, a first photonic integrated circuit (PIC) die 104, and a second PIC die 106. Optional fiber array units (FAUs) may be added. The PIC die 104 is operably connected to fiber array unit (FAU) 108 and the PIC die 106 is operably connected to FAU 110. As may be appreciated, this arrangement of die is just one example embodiment, in other multi-die assemblies, there may be more or less PIC die, more or less FAU components, more or less ICs, and the die may be arranged in any pattern (e.g., square (e.g., 2×2, 4×4, 6×6), rectangular (e.g., 2×4, 3×5, 4×7)). The die may be attached to a substrate 112. In various embodiments, the substrate 112 may comprise a printed circuit board, thin-film substrate, or another suitable substrate. In other embodiments, the substrate 112 may further be attached to a printed circuit board (PCB) 114; and in further embodiments, the multi-die assembly may include additional IC die, represented generally as die 118.

In various embodiments, the die in the semiconductor package 100 can be overmolded with an encapsulant 116. The encapsulant 116 can comprise a molding compound, dielectric materials, metal, ceramic, plastic, or a combination thereof. Additionally, a thermal management solution (not shown) comprising a cooling component such as a vapor chamber, heat pipe, heat sink, or liquid-cooled cold plate may be attached to a semiconductor package 100. As part of a thermal management solution, a thermal conduction layer interface material (TIM) may be located over the die 102. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

The die 102, 104, 106, and 118, may be unpackaged integrated circuit die, and may alternatively be referred to as chips, chiplets, chip complexes, or chiplet complexes. The PICs employ at least some optical communication, and the fiber array units (FAUs) implement optical switching functionality. While the terms die, chip, and chiplet may be used interchangeably, the term chiplet is sometimes used to refer to an integrated circuit die that implements a subset of the functionality of a larger integrated circuit component. Although the illustration depicts the chiplets as having uniform dimensions, in practice, chiplet dimensions (lateral dimensions, as well as thickness) and shape can vary among chiplets; moreover, the chiplets may vary by type/functionality (e.g., compute, memory, I/O, power management (controlling the delivery of power and/or providing power to components)). Any integrated circuit die, chip, or chiplet can implement any portion of the functionality of any processor unit described or referenced herein. Furthermore, a semiconductor package 100 can have any shape, such as a substantially square shape, substantially rectangular shape, or substantially circular shape.

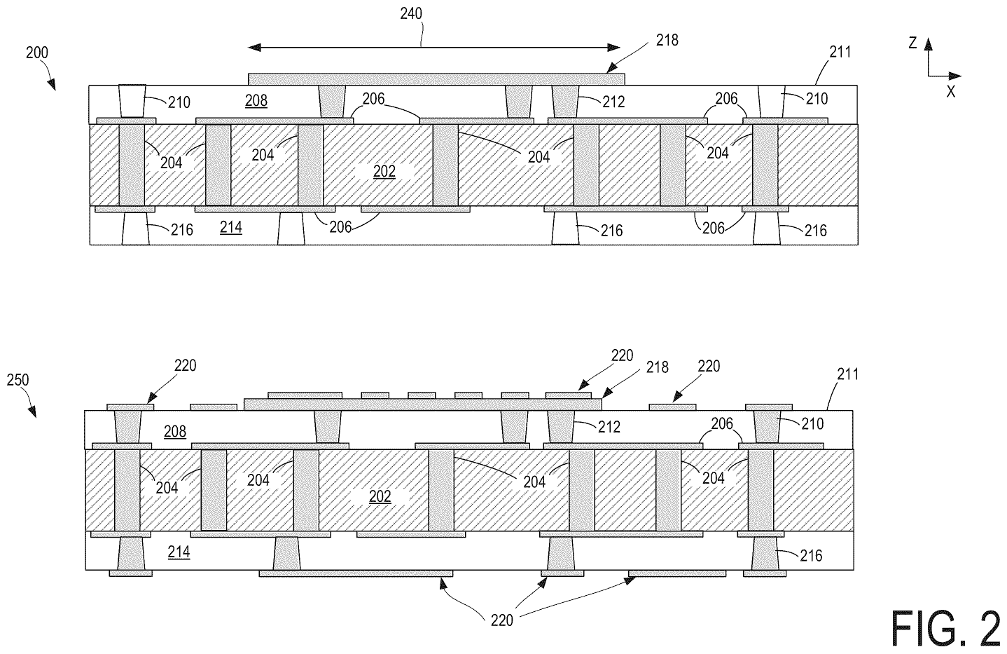

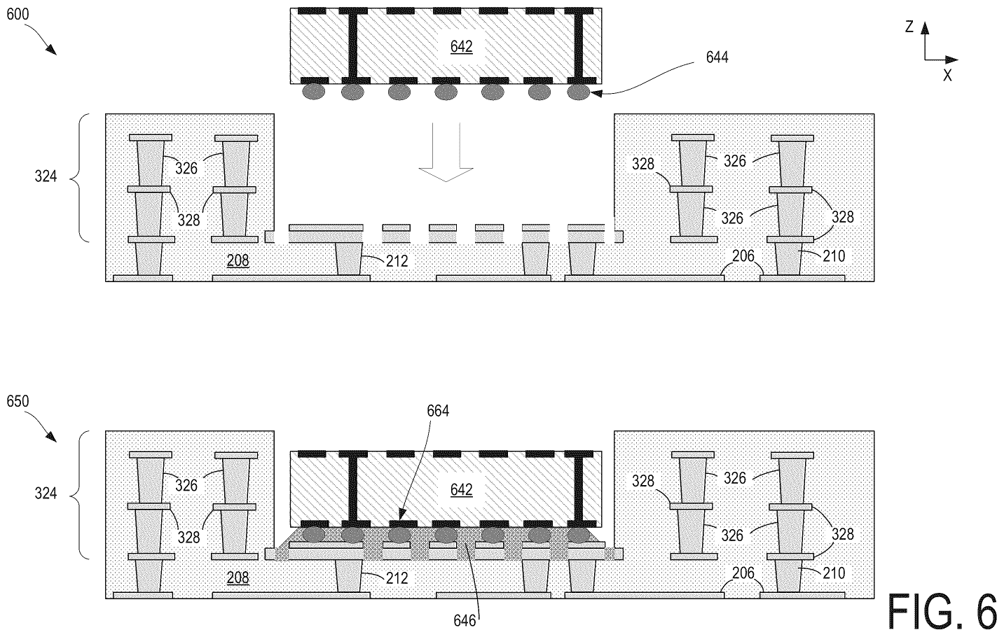

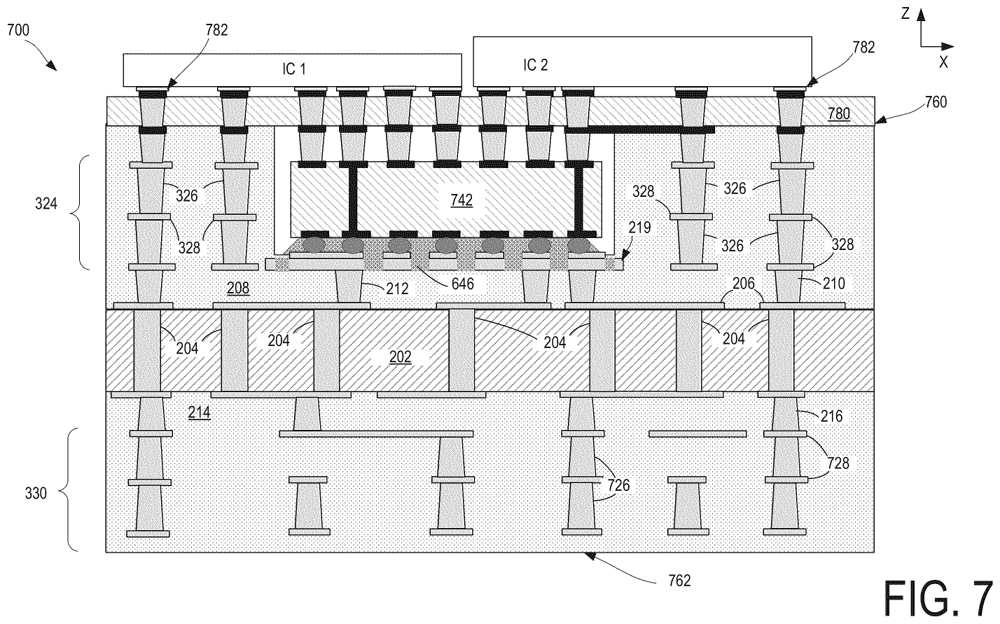

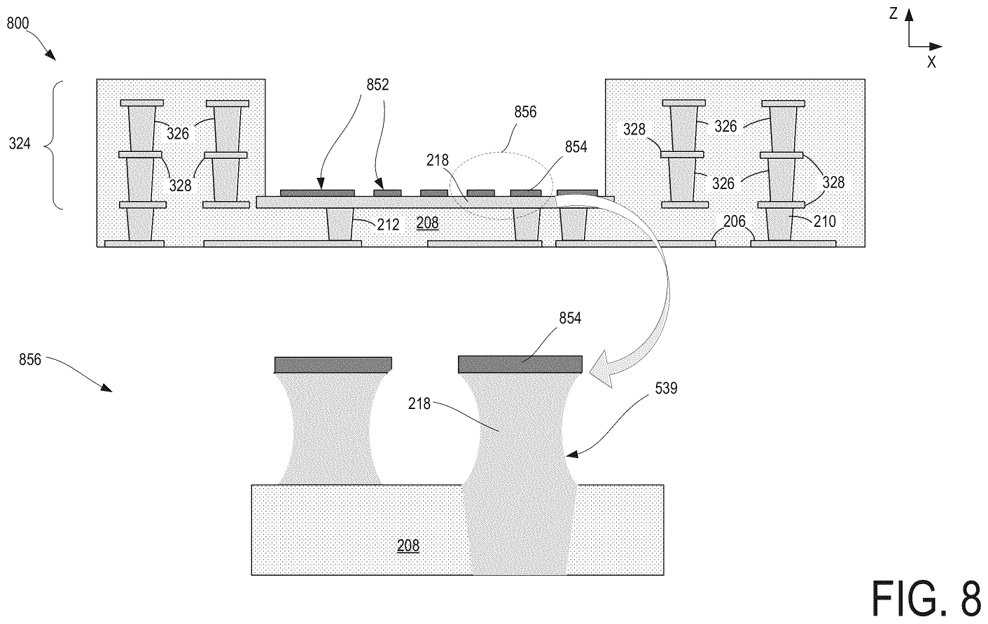

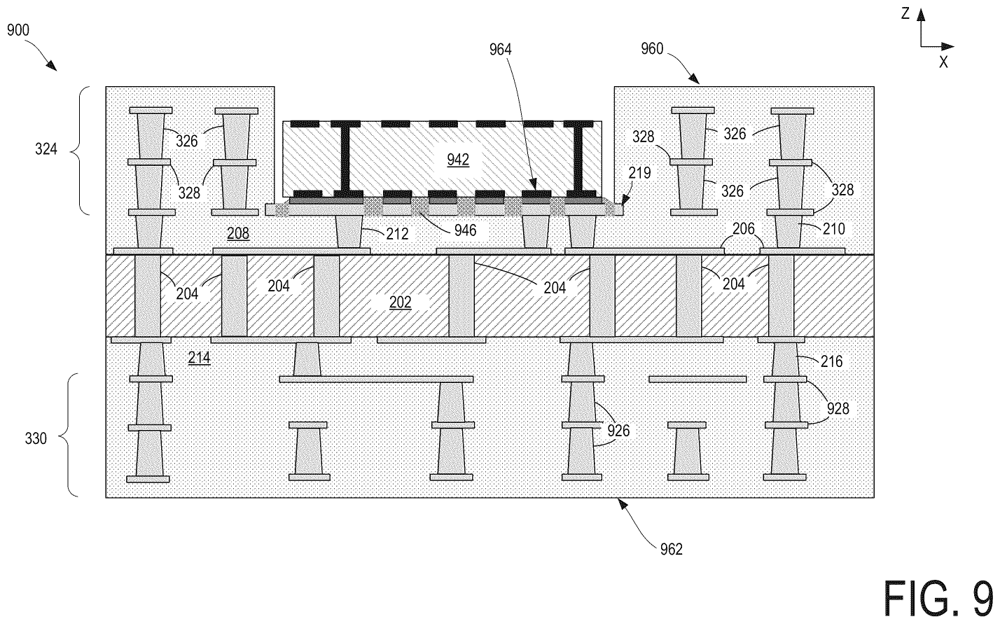

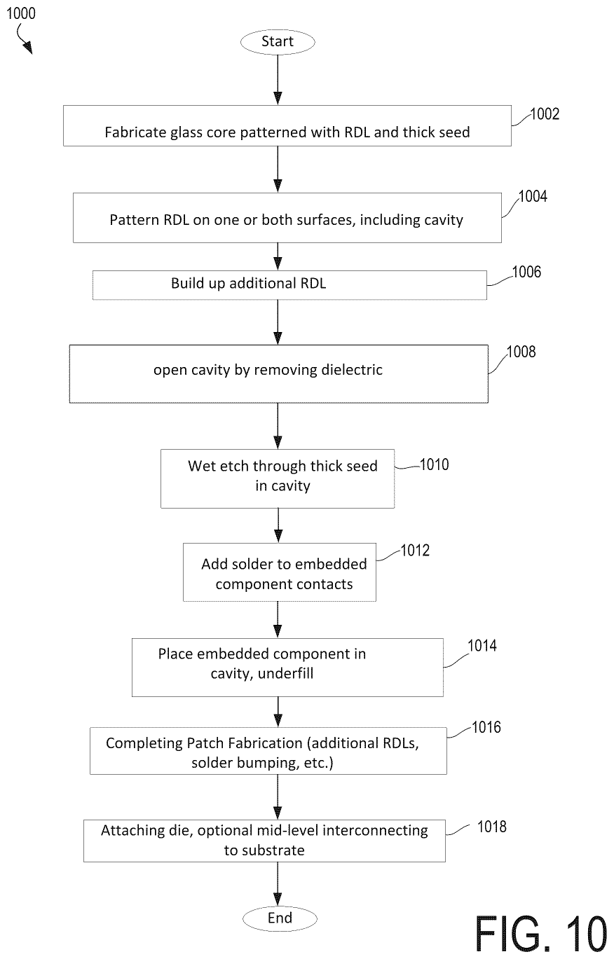

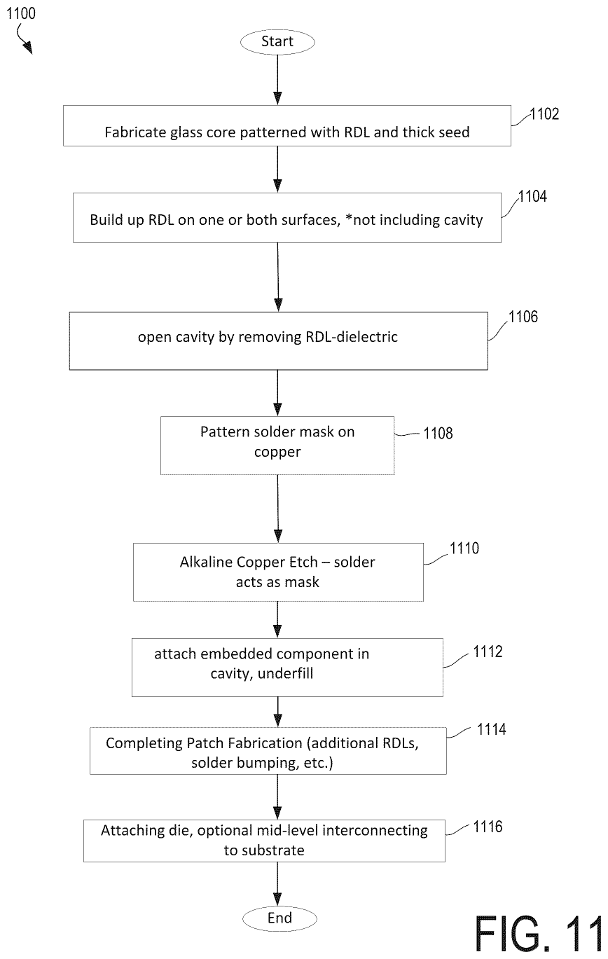

The dashed line 120 narrows the focus to an area of the substrate package 112 that includes redistribution layers in a dielectric cavity to enable an embedded component. FIGS. 2-9 provide various stages of fabrication of a substrate showing embodiments of redistribution layers in a dielectric cavity to enable an embedded component. This substrate view is sometimes referred to as a substrate package or “substrate patch.” FIGS. 10 and 11 provide a process flow for creating embodiments described herein.

The substrate package or substrate for embodiments includes a glass core, as illustrated in FIG. 2. Embodiment 200 illustrates (at 1002) a glass layer or glass core 202 patterned with through-holes or through glass vias (TGVs) 204. The glass core 202 may comprise glass, (as used herein, glass can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO₂, Al₂O₃, B₂O₃, and MgO), or a photosensitive glass (photomachineable or photostructurable glass). In some embodiments, a photosensitive glass can be a glass that belongs to the lithium-silicate family of glass (e.g., a glass comprising lithium, silicon, and oxygen) comprising metallic particles, such as gold, silver, or other suitable metallic particles. Glass core 202 may comprise multiple glass sheets bonded together with an adhesion layer. In various embodiments, the glass core 202 may have a thickness in a range of about 20 microns to about 1 millimeter, +/−10%.

A dielectric layer 208 with RDL conductive traces 206 is patterned and located on an upper surface. Various embodiment may also have a dielectric layer 214 with RDL conductive traces 206 patterned and located on a lower surface of the glass core 202. The dielectric layers 208 and 214 can be a suitable nitride or oxide, such as silicon dioxide (SiO₂), carbon-doped silicon dioxide, fluorine-doped silicon dioxide, hydrogen-doped silicon dioxide, or silicon nitride. The dielectric layer 208 has vias or pillars 210, and the dielectric layer 214 has vias or pillars 216. As illustrated in embodiment 250, the vias or pillars 210, 212, and 216, as well as the TGVs 204 are substantially perpendicular to an upper surface 211 of the glass core 202.

As mentioned, the glass layer 202 may be called a glass core. Additionally, the “core” may be a combination of glass and epoxy. Accordingly, in various embodiments, an epoxy layer (not shown) may be located adjacent to the glass layer 202 and between the glass layer 202 and the dielectric layer 214. The Epoxy layer may include epoxy resin, a fiberglass-reinforced epoxy resin, an epoxy resin with inorganic fillers, a ceramic material, or a polymer material such as polyimide.

A layer of conductive material or seed 218 is overlaid on a portion of the upper surface 211 of the dielectric layer 208 that is designated to be a dielectric cavity to enable an embedded component, as is further developed with subsequent illustrations. As may be appreciated, the cavity portion comprises a smaller width, area, or volume, of an overall substrate under discussion. Accordingly, as the seed 218 is intended for the cavity floor, the width of the seed 218 is less than a width of the glass core 202 and dielectric layers. Additionally, the width of the seed 218 is a function of a width of a target embedded component. The figures reflect cross-sectional views, in which the portion for the dielectric cavity is depicted as a width; however, in a top-down view, the portion for the dielectric cavity (and hence the seed 218) would appear as an area.

In various embodiments, the seed 218 may comprise a width 240 of from about 5 microns to about 40 microns in the X direction (or in the Y direction coming out of the page), along the upper surface 211. Respective vias 212 under the seed 218 are filled concurrent with placing the thick seed 218, as indicated with shading in the figure.

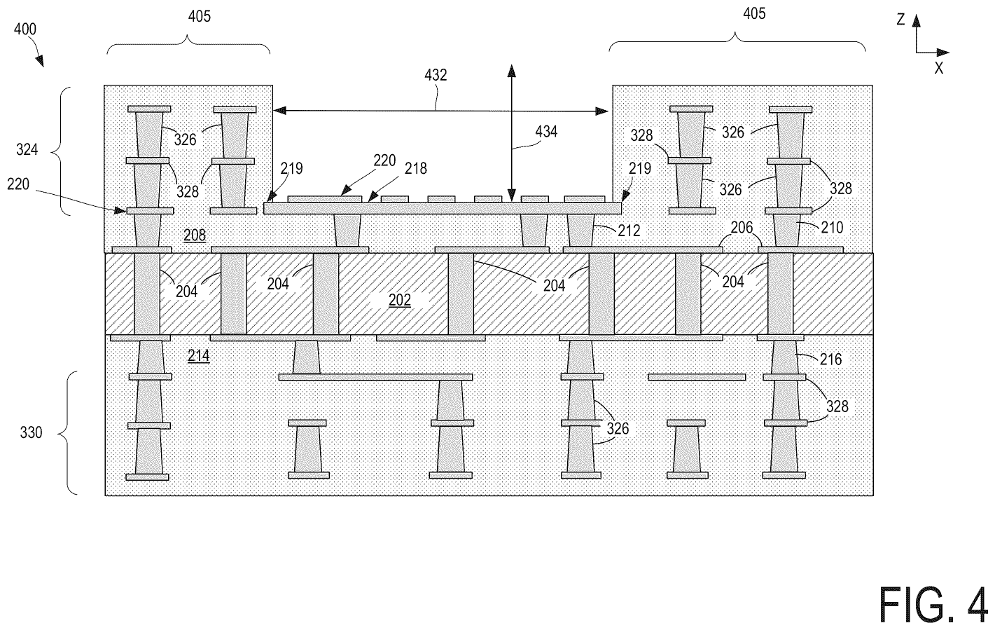

The seed 218 functions as a laser stop (described in more detail in connection with FIG. 4), and therefore may be thicker than conductive material used for other conductive traces in RDL; accordingly, seed 218 is also referred to as “thick seed.” The thick seed 218 may comprise a metal (e.g., copper, aluminum, nickel, cobalt, iron, tin, gold, silver, or combinations thereof) or another suitable conductive material. The thick seed 218 may have a thickness (measured in the Z direction in the figure) from about 1 micron to 10 microns. In various embodiments, the thick seed 218 may be substantially 5 microns.

At 1004, embodiment 250 illustrates a RDL (represented by conductive traces 220) patterned at the upper surface (including over the thick seed 218) and at the lower surface. Any vias 210 and 216 associated with the RDL are filled in this process, as illustrated with the color change from white to gray. In the figures, the seed 218 is located in between the dielectric layer 208 adjacent to the glass core 202 and another RDL (conductive traces 220). Embodiment 250 is a potential product having the RDL in the target location for a dielectric cavity to enable the embedded component. The RDL patterning may be performed using a modified semi-additive plating (MSAP) process, placing the thick seed 218 and then patterning cavity RDL overtop of the seed.

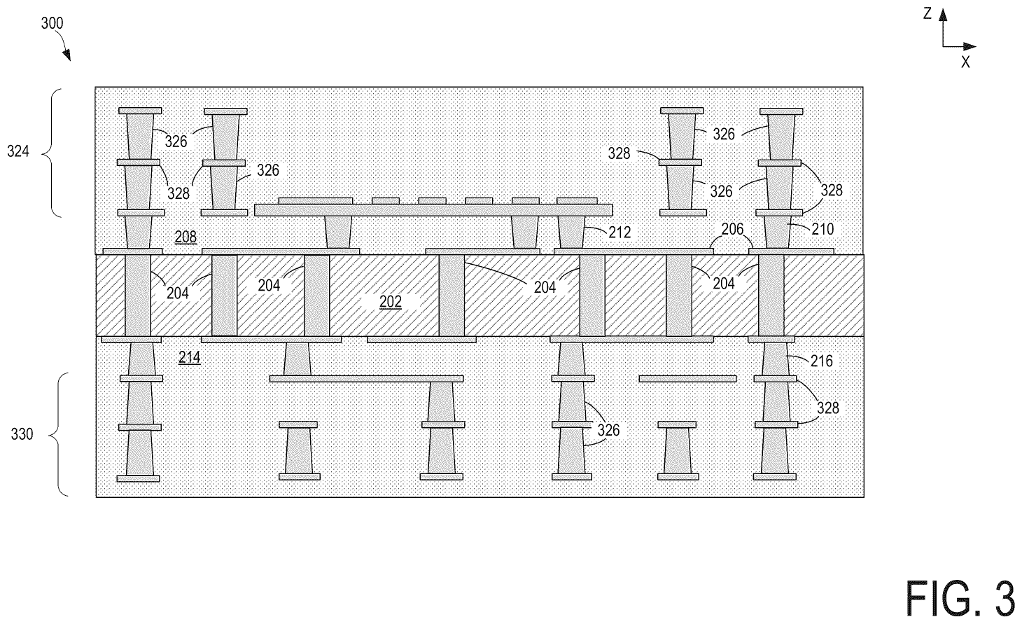

At 1006, and with reference to FIG. 3, one or more additional dielectric layers 324 with RDL may be added to the upper surface. Additionally, one or more dielectric layers 330 may be added to the lower surface of the embodiment 250. In the non-limiting example embodiment 300, dielectric layer 324 on the upper surface further includes two more layers of RDL conductive traces 328 and vias 326, and dielectric layer 330 on the lower surface further includes two more layers of RDL conductive traces 328 and vias 326. The dielectric layers 324 and 330 with RDL may be manufactured in accordance with conventional methodologies.

In various embodiments, the dielectric layer 324 and 330 can include, overlaid on the conductive trace material, a dielectric material, such as, a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, a dielectric layer comprises a photo-imagable dielectric (PID). In some embodiments, the dielectric layer comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df)).

In some embodiments, it is advantageous for the dielectric layer to have a CTE that matches that of target integrated circuit or PIC dies (e.g., match the CTE of silicon) attached to a substrate or PCB. In some embodiments, the dielectric material can have a CTE that is close (e.g., within 10%) to that of silicon. In other embodiments, the dielectric material can be any type of epoxy molding compound.

Individual dielectric layers 324 and/or 330 may comprise multiple RDL conductive traces layered therein. In the example shown in FIG. 3, vertical traces 326 and lateral traces 328 are located in dielectric layers 324 and 330, built up (in a Z direction in the figure) on a top surface or front side of the core 202, and on a back side of the glass core 202, respectively.

As with other RDL conductive traces described herein, the conductive traces 326 and 328 comprise electrically conductive material, such as, a metal (e.g., copper, aluminum, nickel, cobalt, iron, tin, gold, silver, or combinations thereof) or another suitable conductive material, and provide electrically conductive paths from an origin to a terminus of the respective trace. The dielectric layers 330 and 324 can be a suitable nitride or oxide, such as silicon dioxide (SiO₂), carbon-doped silicon dioxide, fluorine-doped silicon dioxide, hydrogen-doped silicon dioxide, or silicon nitride.

In other embodiments, there may be more or less layers of RDL in dielectric layers 324 and more or less layers of RDL in dielectric layers 330, and the number of RDL dielectric layers 324 does not necessarily match the number of RDL in dielectric layers 330.

At 1008, the dielectric cavity is created in the substrate by removing dielectric material to expose the RDL over the thick seed 218 (embodiment 400). A laser drill or ablation process may be used to remove the dielectric material and create the dielectric cavity located on the thick seed 218. The cavity has a cavity depth 434 and a cavity width 432. Cavity walls 405 are substantially straight and may have an internal taper reflecting the drill or ablation process used to open the cavity. The thick seed 218 acts as a laser stop, enforcing a floor to the cavity. When viewing the shape of the cavity, it is notable that the cavity width 432 is smaller than the thick seed width 240, which results in a lip or corner ledges 219 located around the periphery of the floor of the dielectric cavity, as depicted in the two-dimensional figures.

Another way to describe embodiment 400 is to describe the cavity walls 405 as substantially perpendicular to the thick seed 218, encircling a periphery of the thick seed 218, and comprising at least one dielectric layer. For example, wherein the thick seed 218 is located in a first portion of the substrate, the cavity wall 405 is located external to the first portion. The first dielectric layer 208 extends past a periphery of the conductive layer (thick seed 218), where the cavity wall 405 is located, so the first dielectric layer 208 becomes a base (with respect to the figures (e.g., FIG. 4) for the cavity wall 405, and various embodiments further comprise a third dielectric layer 324 located on the RDL 220 in the cavity walls 405, but not located on RDL 220 in the cavity (in this example, the first dielectric layer is 208, the second dielectric layer is 214, and the third dielectric layer is 324, a fourth dielectric layer may be 330).

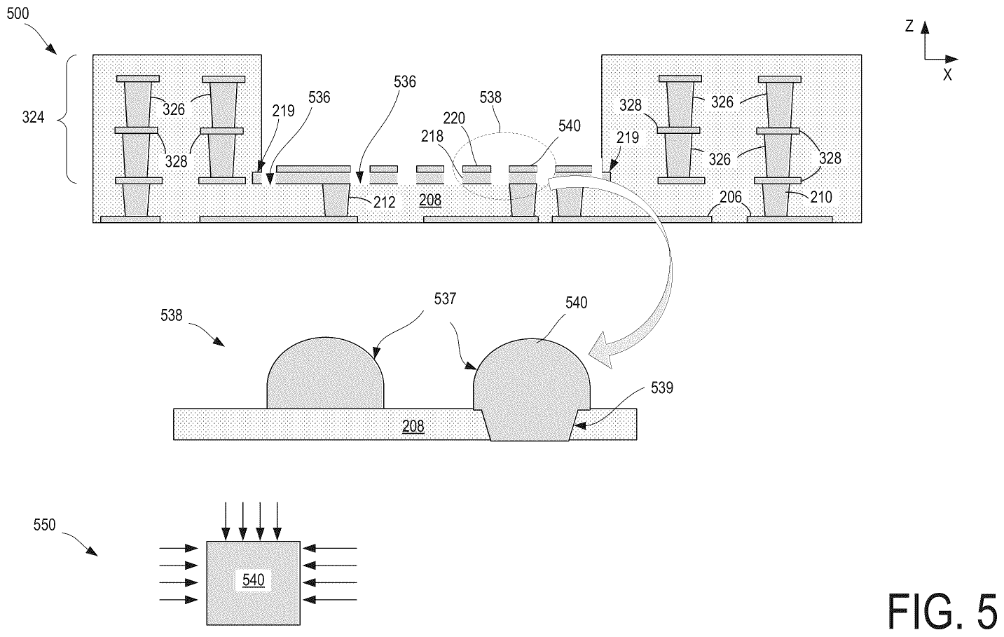

At 1010, the thick seed 218 is removed from non-RDL locations in the cavity. This task may be performed using an isotropic wet etch. Moving to FIG. 5, embodiment 500 depicts the thick seed 218 removed in areas 536 not covered by RDL traces 220. To simplify this discussion, the glass core 202 and dielectric layers 330 are omitted in some of the illustrations, but those with skill in the art will appreciate that they continue to be present. Although this image depicts the RDL conductive traces in the dielectric cavity (i.e., those that are located on the thick seed 218) with straight edges, in practice, a wet etch process will subject the conductive traces to corner effects (see the arrows in embodiment 550), which will cause the shape of the contacts to appear rounded. Accordingly, area 538, with contact/via 540, is shown enlarged to present this concept. A surface 537 of the contacts and contact/vias (e.g., contact 540) may be viewed in a scanning electron micrograph (SEM) image as having curvature, as illustrated. Said differently, any tangent lines that might be drawn along surface 537 would likely only make contact with the surface 537 at one point, therefore a straight slope could not be calculated. This is distinguished from other solutions in which the RDL contacts would exhibit a straight surface with a taper or slope on SEM images.

At 1012, solder bumps 644 can be added to the conductive contacts 664 on the embedded component 642 to be placed in the dielectric cavity (embodiment 600). At 1014, the embedded component 642 can be positioned in the dielectric cavity such that the solder bumps align with the RDL conductive contacts and traces in the dielectric cavity (embodiment 650). Underfill 646 may also be added between the embedded component 642 and the cavity floor. At 1014, the components in the embodiment may support operational communication with each other and may provide in a multi-die package the functionality conventionally associated with a monolithic system on chip (SoC). In various embodiments, at least one electrically communicative path from the first dielectric layer through a TGV to the second dielectric layer is a power route.

At 1016 the substrate (e.g., embodiment 650) may be subjected to further patch fabrication, as illustrated in embodiment 700. For example, the upper surface 760 of the patch may planarized and more dielectric layers 780 with one or more RDL therein may be added to the upper surface. Further, overmolding and thermal solutions (not shown) may be added. Additionally, solder bumps may be added to the lower surface 762, etc. At 1018, additional die may be added, and optional mid-level interconnections may be added.

In various embodiments, the solder material for solder bumps 782 used to attach die IC 1 and die IC 2 has a lower melting point than solder used for solder bumps 644 on the embedded component. In an embodiment, the solder material for solder bumps 782 may be a solder alloy such as tin and gold, or the like. In another embodiment, the solder material for solder bumps 644 could be tin and the solder material for solder bumps 782 could be a tin and gold compound. This increases the reliability of the solder attach of the embedded component (and by extension, any product that includes the embodiment) by preventing the embedded component to loosen or move around when heat is applied to attach die at the upper surface. Also, at 1018, the components in the embodiment may support operational communication with each other. A SEM image of any of these embodiments would show the previously described corner ledge 219 of the thick seed 218 at the corners of the dielectric cavity.

In an alternative embodiment 800, solder 852 may be patterned directly into a dielectric cavity on the thick seed 218, in a different SAP step. To arrive at this embodiment, at 1102, a glass core 202 is patterned with RDL and thick seed, as described above. At 1104, dielectric and RDL is built up on one or both surfaces, but RDL is not located on the thick seed 218. Dielectric is removed, creating the dielectric cavity. In this embodiment, the thick seed 218 again acts as a stop for the laser drill or etch process, as described above, however, instead of using a RDL conductive trace on the thick seed 218, this embodiment uses the solder to perform this functionality. At 1108, solder 852 is patterned on the thick seed 218.

A copper etch can then be performed (at 1110) to remove the thick seed 218 where it isn't needed in the dielectric cavity. In this scenario, the solder 852 acts as a mask during a subtractive etch, such as an alkaline copper etch, resulting in a contact/via shape 854 in which the walls of the thick seed 218 are scalloped on the contacts. Area 856 is enlarged below the embodiment 800 to illustrate the scallop 539 shape in contact/via 854.

In embodiment 900, embedded component 942 is positioned in the dielectric cavity such that the conductive contacts 964 in the embedded component 942 align with the solder contacts in the solder 852 patterning in the dielectric cavity (embodiment 900, at 1112). Underfill 946 may also be added. At 1114, patch fabrication may be completed, at 1116, die and mid-level interconnect may be added; see the discussion of 1016 and 1018 above for further details on these procedures.

Thus, various non-limiting embodiments of redistribution layers in a dielectric cavity to enable an embedded component have been described. The disclosed embodiments pattern redistribution layers (RDL) over a thick seed in the fabrication process and remove dielectric to create the dielectric cavity. Embodiments exhibit distinct features in SEM images, such as, thick seed ledges in the dielectric around the floor of the dielectric cavity and either spherical or scalloped contacts in the RDL in the dielectric cavity. Embodiments enable 2-sided connections for embedded components with minimal disruption to existing process infrastructure. Such an approach can be used not only for integration of photonic devices, but also for any architecture requiring dual sided connection within a cavity, for example, embedded silicon bridges. The following description provides additional detail and context for various die and various package assembly and device configurations that can be created based on or using the provided embodiments.

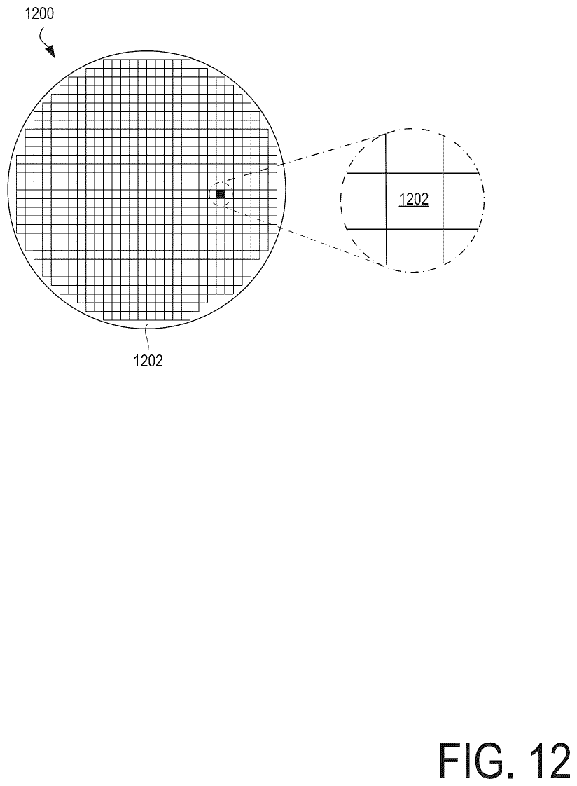

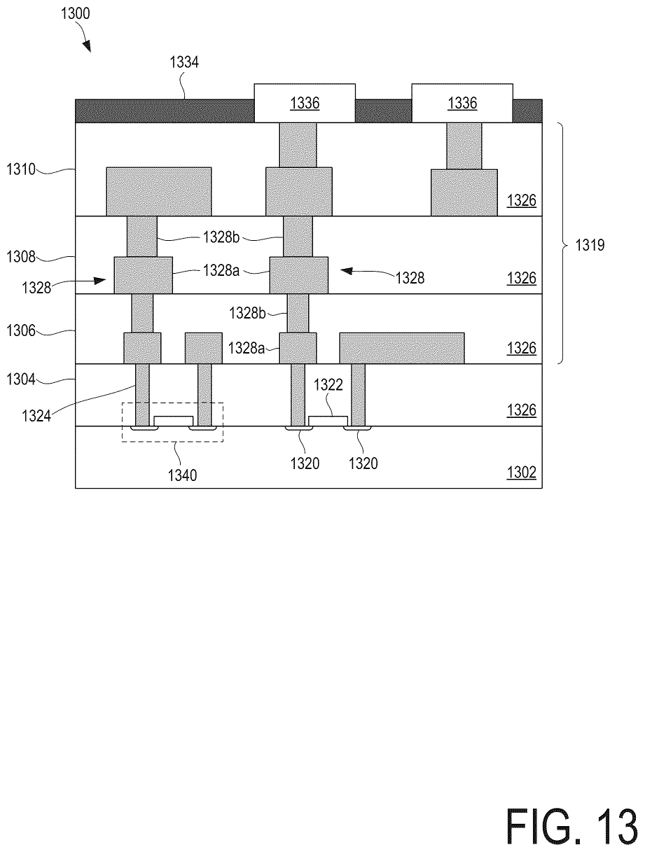

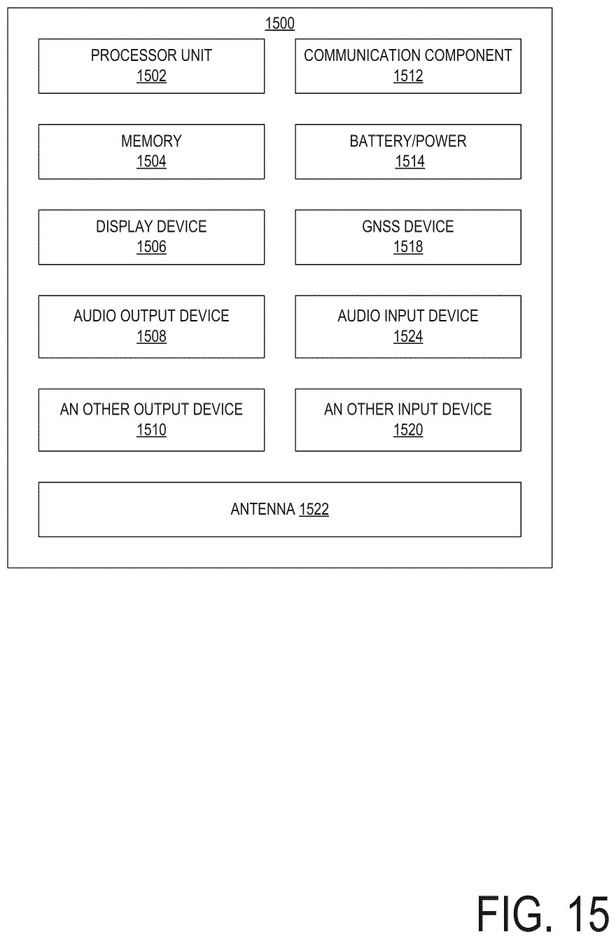

FIG. 12 is a top view of a wafer 1200 and dies 1202 that may be included in any of the embodiments disclosed herein. The wafer 1200 may be composed of semiconductor material and may include one or more dies 1202 formed on a surface of the wafer 1200. After the fabrication of the integrated circuit components on the wafer 1200 is complete, the wafer 1200 may undergo a singulation process in which the dies 1202 are separated from one another to provide discrete “chips” or destined for a packaged integrated circuit component. The individual dies 1202, comprising an integrated circuit component, may include one or more transistors (e.g., some of the transistors 1340 of FIG. 13, discussed below), supporting circuitry to route electrical signals to the transistors, passive components (e.g., signal traces, resistors, capacitors, or inductors), and/or any other integrated circuit components. In some embodiments, the wafer 1200 or the die 1202 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 1202. For example, a memory array formed by multiple memory devices may be formed on a same die 1202 as a processor unit (e.g., the processor unit 1502 of FIG. 15) or other logic that is configured to store information in the memory devices or execute instructions stored in the memory array. In some embodiments, a die 1202 may be attached to a wafer 1200 that includes other die, and the wafer 1200 is subsequently singulated, this manufacturing procedure is referred to as a die-to-wafer assembly technique.

FIG. 13 is a cross-sectional side view of an integrated circuit 1300 that may be included in any of the embodiments disclosed herein. One or more of the integrated circuits 1300 may be included in one or more dies 1202 (FIG. 12). The integrated circuit 1300 may be formed on a die substrate 1302 (e.g., the wafer 1200 of FIG. 12) and may be included in a die (e.g., the die 1202 of FIG. 12).

The die substrate 1302 may be a semiconductor substrate composed of semiconductor material systems including, for example, n-type or p-type materials systems (or a combination of both). The die substrate 1302 may include, for example, a crystalline substrate formed using a bulk silicon or a silicon-on-insulator (SOI) substructure. In some embodiments, the die substrate 1302 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1302. Although a few examples of materials from which the die substrate 1302 may be formed are described here, any material that may serve as a foundation for an integrated circuit 1300 may be used. The die substrate 1302 may be part of a singulated die (e.g., the dies 1202 of FIG. 12) or a wafer (e.g., the wafer 1200 of FIG. 12).

The integrated circuit 1300 may include one or more device layers 1304 disposed on the die substrate 1302. The device layer 1304 may include features of one or more transistors 1340 (e.g., metal oxide semiconductor field-effect transistors (MOSFETs)) formed on the die substrate 1302. The transistors 1340 may include, for example, one or more source and/or drain (S/D) regions 1320, a gate 1322 to control current flow between the S/D regions 1320, and one or more S/D contacts 1324 to route electrical signals to/from the S/D regions 1320.

The gate 1322 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1340 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1340 along the source-channel-drain direction, the gate electrode may comprise a U-shaped structure that includes a bottom portion substantially parallel to the surface of the die substrate 1302 and two sidewall portions that are substantially perpendicular to the top surface of the die substrate 1302. In other embodiments, at least one of the metal layers that form the gate electrode may simply be a planar layer that is substantially parallel to the top surface of the die substrate 1302 and does not include sidewall portions substantially perpendicular to the top surface of the die substrate 1302. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching processes. In some embodiments, a plurality of spacer pairs may be used; for instance, two pairs, three pairs, or four pairs of sidewall spacers may be formed on opposing sides of the gate stack.

The S/D regions 1320 may be formed within the die substrate 1302 adjacent to the gate 1322 of individual transistors 1340. The S/D regions 1320 may be formed using an implantation/diffusion process or an etching/deposition process, for example. In the former process, dopants such as boron, aluminum, antimony, phosphorous, or arsenic may be ion-implanted into the die substrate 1302 to form the S/D regions 1320. An annealing process that activates the dopants and causes them to diffuse farther into the die substrate 1302 may follow the ion-implantation process. In the latter process, the die substrate 1302 may first be etched to form recesses at the locations of the S/D regions 1320. An epitaxial deposition process may then be conducted to fill the recesses with material that is used to fabricate the S/D regions 1320. In some implementations, the S/D regions 1320 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1320 may be formed using one or more alternate semiconductor materials such as germanium or a group III-V material or alloy. In further embodiments, one or more layers of metal and/or metal alloys may be used to form the S/D regions 1320.

Electrical signals, such as power and/or input/output (I/O) signals, may be routed to and/or from the devices (e.g., transistors 1340) of the device layer 1304 through one or more interconnect layers disposed on the device layer 1304 (illustrated in FIG. 13 as interconnect layers 1306-1310). For example, electrically conductive features of the device layer 1304 (e.g., the gate 1322 and the S/D contacts 1324) may be electrically coupled with the interconnect structures 1328 of the interconnect layers 1306-1310. The one or more interconnect layers 1306-1310 may form a metallization stack (also referred to as an “ILD stack”) 1319 of the integrated circuit 1300.

The interconnect structures 1328 may be arranged within the interconnect layers 1306-1310 to route electrical signals according to a wide variety of designs; in particular, the arrangement is not limited to the particular configuration of interconnect structures 1328 depicted in FIG. 13. Although a particular number of interconnect layers 1306-1310 is depicted in FIG. 13, embodiments of the present disclosure include integrated circuits having more or fewer interconnect layers than depicted.

In some embodiments, the interconnect structures 1328 may include lines 1328a and/or vias 1328b filled with an electrically conductive material such as a metal. The lines 1328a may be arranged to route electrical signals in a direction of a plane that is substantially parallel with a surface of the die substrate 1302 upon which the device layer 1304 is formed. For example, the lines 1328a may route electrical signals in a direction in and out of the page and/or in a direction across the page. The vias 1328b may be arranged to route electrical signals in a direction of a plane that is substantially perpendicular to the surface of the die substrate 1302 upon which the device layer 1304 is formed. In some embodiments, the vias 1328b may electrically couple lines 1328a of different interconnect layers 1306-1310 together.

The interconnect layers 1306-1310 may include a dielectric material 1326 disposed between the interconnect structures 1328, as shown in FIG. 13. In some embodiments, dielectric material 1326 disposed between the interconnect structures 1328 in different ones of the interconnect layers 1306-1310 may have different compositions; in other embodiments, the composition of the dielectric material 1326 between different interconnect layers 1306-1310 may be the same. The device layer 1304 may include a dielectric material 1326 disposed between the transistors 1340 and a bottom layer of the metallization stack as well. The dielectric material 1326 included in the device layer 1304 may have a different composition than the dielectric material 1326 included in the interconnect layers 1306-1310; in other embodiments, the composition of the dielectric material 1326 in the device layer 1304 may be the same as a dielectric material 1326 included in any one of the interconnect layers 1306-1310.

A first interconnect layer 1306 (referred to as Metal 1 or “M1”) may be formed directly on the device layer 1304. In some embodiments, the first interconnect layer 1306 may include lines 1328a and/or vias 1328b, as shown. The lines 1328a of the first interconnect layer 1306 may be coupled with contacts (e.g., the S/D contacts 1324) of the device layer 1304. The vias 1328b of the first interconnect layer 1306 may be coupled with the lines 1328a of a second interconnect layer 1308.

The second interconnect layer 1308 (referred to as Metal 2 or “M2”) may be formed directly on the first interconnect layer 1306. In some embodiments, the second interconnect layer 1308 may include via 1328b to couple the lines 1328 of the second interconnect layer 1308 with the lines 1328a of a third interconnect layer 1310. Although the lines 1328a and the vias 1328b are structurally delineated with a line within individual interconnect layers for the sake of clarity, the lines 1328a and the vias 1328b may be structurally and/or materially contiguous (e.g., simultaneously filled during a dual-damascene process) in some embodiments.

The third interconnect layer 1310 (referred to as Metal 3 or “M3”) (and additional interconnect layers, as desired) may be formed in succession on the second interconnect layer 1308 according to similar techniques and configurations described in connection with the second interconnect layer 1308 or the first interconnect layer 1306. In some embodiments, the interconnect layers that are “higher up” in the metallization stack 1319 in the integrated circuit 1300 (i.e., farther away from the device layer 1304) may be thicker that the interconnect layers that are lower in the metallization stack 1319, with lines 1328a and vias 1328b in the higher interconnect layers being thicker than those in the lower interconnect layers.

The integrated circuit 1300 may include a solder resist material 1334 (e.g., polyimide or similar material) and one or more conductive contacts 1336 formed on the interconnect layers 1306-1310. In FIG. 13, the conductive contacts 1336 are illustrated as taking the form of bond pads. The conductive contacts 1336 may be electrically coupled with the interconnect structures 1328 and configured to route the electrical signals of the transistor(s) 1340 to external devices. For example, solder bonds may be formed on the one or more conductive contacts 1336 to mechanically and/or electrically couple an integrated circuit die including the integrated circuit 1300 with another component (e.g., a printed circuit board). The integrated circuit 1300 may include additional or alternate structures to route the electrical signals from the interconnect layers 1306-1310; for example, the conductive contacts 1336 may include other analogous features (e.g., posts) that route the electrical signals to external components.

In some embodiments in which the integrated circuit 1300 is a double-sided die, the integrated circuit 1300 may include another metallization stack (not shown) on the opposite side of the device layer(s) 1304. This metallization stack may include multiple interconnect layers as discussed above with reference to the interconnect layers 1306-1310, to provide electrically conductive paths (e.g., including conductive lines and vias) between the device layer(s) 1304 and additional conductive contacts (not shown) on the opposite side of the integrated circuit 1300 from the conductive contacts 1336.

In other embodiments in which the integrated circuit 1300 is a double-sided die, the integrated circuit 1300 may include one or more through-silicon vias (TSVs) through the die substrate 1302; these TSVs may make contact with the device layer(s) 1304, and may provide electrically conductive paths between the device layer(s) 1304 and additional conductive contacts (not shown) on the opposite side of the integrated circuit 1300 from the conductive contacts 1336. In some embodiments, TSVs extending through the substrate can be used for routing power and ground signals from conductive contacts on the opposite side of the integrated circuit 1300 from the conductive contacts 1336 to the transistors 1340 and any other components integrated into the die 1300, and the metallization stack 1319 can be used to route I/O signals from the conductive contacts 1336 to transistors 1340 and any other components integrated into the die 1300.

Multiple integrated circuits 1300 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

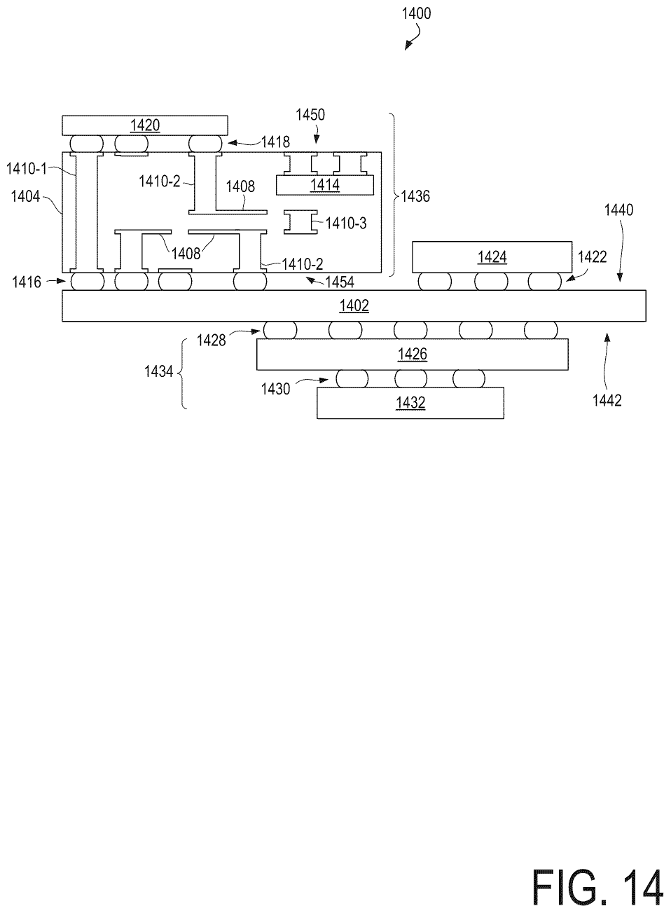

FIG. 14 is a cross-sectional side view of a microelectronic assembly 1400 that may include any of the embodiments disclosed herein. The microelectronic assembly 1400 includes multiple integrated circuit components disposed on a circuit board 1402 (which may be a motherboard, system board, mainboard, etc.). The microelectronic assembly 1400 may include components disposed on a first face 1440 of the circuit board 1402 and an opposing second face 1442 of the circuit board 1402; generally, components may be disposed on one or both faces 1440 and 1442.

In some embodiments, the circuit board 1402 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1402. In other embodiments, the circuit board 1402 may be a non-PCB substrate. The microelectronic assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1436 may include an integrated circuit component 1420 coupled to an interposer 1404 by coupling components 1418. The coupling components 1418 may take any suitable form for the application, such as the forms discussed above with reference to the coupling components 1416. Although a single integrated circuit component 1420 is shown in FIG. 14, multiple integrated circuit components may be coupled to the interposer 1404; indeed, additional interposers may be coupled to the interposer 1404. The interposer 1404 may provide an intervening substrate used to bridge the circuit board 1402 and the integrated circuit component 1420.

The integrated circuit component 1420 may be a packaged or unpackaged integrated circuit component that includes one or more integrated circuit dies (e.g., the die 1202 of FIG. 12, the integrated circuit 1300 of FIG. 13) and/or one or more other suitable components.

The unpackaged integrated circuit component 1420 comprises solder bumps attached to contacts on the die. The solder bumps allow the die to be directly attached to the interposer 1404. In embodiments where the integrated circuit component 1420 comprises multiple integrated circuit die, the dies can be of the same type (a homogeneous multi-die integrated circuit component) or of two or more different types (a heterogeneous multi-die integrated circuit component). In addition to comprising one or more processor units, the integrated circuit component 1420 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1404 may spread connections to a wider pitch or reroute a connection to a different connection. For example, the interposer 1404 may couple the integrated circuit component 1420 to a set of ball grid array (BGA) conductive contacts of the coupling components 1416 for coupling to the circuit board 1402. In the embodiment illustrated in FIG. 14, the integrated circuit component 1420 and the circuit board 1402 are attached to opposing sides of the interposer 1404; in other embodiments, the integrated circuit component 1420 and the circuit board 1402 may be attached to a same side of the interposer 1404. In some embodiments, three or more components may be interconnected by way of the interposer 1404.

In some embodiments, the interposer 1404 may be formed as a PCB, including multiple metal layers separated from one another by layers of dielectric material and interconnected by electrically conductive vias. In some embodiments, the interposer 1404 may be formed of an epoxy resin, a fiberglass-reinforced epoxy resin, an epoxy resin with inorganic fillers, a ceramic material, or a polymer material such as polyimide. In some embodiments, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through hole vias 1410-1 (that extend from a first face 1450 of the interposer 1404 to a second face 1454 of the interposer 1404), blind vias 1410-2 (that extend from the first or second faces 1450 or 1454 of the interposer 1404 to an internal metal layer), and buried vias 1410-3 (that connect internal metal layers).

In some embodiments, the interposer 1404 can comprise a silicon interposer. Through-silicon vias (TSV) extending through the silicon interposer can connect connections on a first face of a silicon interposer to an opposing second face of the silicon interposer. In some embodiments, an interposer 1404 comprising a silicon interposer can further comprise one or more routing layers to route connections on a first face of the interposer 1404 to an opposing second face of the interposer 1404.

The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art.

The integrated circuit assembly 1400 may include an integrated circuit component 1424 coupled to the first face 1440 of the circuit board 1402 by coupling components 1422. The coupling components 1422 may take the form of any of the embodiments discussed above with reference to the coupling components 1416, and the integrated circuit component 1424 may take the form of any of the embodiments discussed above with reference to the integrated circuit component 1420.

The integrated circuit assembly 1400 illustrated in FIG. 14 includes a package-on-package structure 1434 coupled to the second face 1442 of the circuit board 1402 by coupling components 1428. The package-on-package structure 1434 may include an integrated circuit component 1426 and an integrated circuit component 1432 coupled together by coupling components 1430 such that the integrated circuit component 1426 is disposed between the circuit board 1402 and the integrated circuit component 1432. The coupling components 1428 and 1430 may take the form of any of the embodiments of the coupling components 1416 discussed above, and the integrated circuit components 1426 and 1432 may take the form of any of the embodiments of the integrated circuit component 1420 discussed above. The package-on-package structure 1434 may be configured in accordance with any of the package-on-package structures known in the art.

FIG. 15 is a block diagram of an example electrical device 1500 that may include one or more of the embodiments disclosed herein. For example, any suitable ones of the components of the electrical device 1500 may include one or more of the microelectronic assemblies 1400, integrated circuit components 1420, integrated circuits 1300, integrated circuit dies 1202, or structures disclosed herein. A number of components are illustrated in FIG. 15 as included in the electrical device 1500, but any one or more of these components may be omitted or duplicated, as suitable for the application. In some embodiments, some or all the components included in the electrical device 1500 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1500 may not include one or more of the components illustrated in FIG. 15, but the electrical device 1500 may include interface circuitry for coupling to the one or more components. For example, the electrical device 1500 may not include a display device 1506, but may include display device interface circuitry (e.g., a connector and driver circuitry) to which a display device 1506 may be coupled. In another set of examples, the electrical device 1500 may not include an audio input device 1524 or an audio output device 1508, but may include audio input or output device interface circuitry (e.g., connectors and supporting circuitry) to which an audio input device 1524 or audio output device 1508 may be coupled.

The electrical device 1500 may include one or more processor units 1502 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1502 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1500 may include a memory 1504, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1504 may include memory that is located on the same integrated circuit die as the processor unit 1502. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1500 can comprise one or more processor units 1502 that are heterogeneous or asymmetric to another processor unit 1502 in the electrical device 1500. There can be a variety of differences between the processor units 1502 in a system in terms of a spectrum of metrics of merit including architectural, microarchitectural, thermal, power consumption characteristics, and the like. These differences can effectively manifest themselves as asymmetry and heterogeneity among the processor units 1502 in the electrical device 1500.

In some embodiments, the electrical device 1500 may include a communication component 1512 (e.g., one or more communication components). For example, the communication component 1512 can manage wireless communications for the transfer of data to and from the electrical device 1500. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1512 may operate in accordance with other wireless protocols in other embodiments. The electrical device 1500 may include an antenna 1522 to facilitate wireless communications and/or to receive other wireless communications (such as AM or FM radio transmissions).

In some embodiments, the communication component 1512 may manage wired communications, such as electrical, optical, or any other suitable communication protocols (e.g., IEEE 802.3 Ethernet standards). As noted above, the communication component 1512 may include multiple communication components. For instance, a first communication component 1512 may be dedicated to shorter-range wireless communications such as Wi-Fi or Bluetooth, and a second communication component 1512 may be dedicated to longer-range wireless communications such as global positioning system (GPS), EDGE, GPRS, CDMA, WiMAX, LTE, EV-DO, or others. In some embodiments, a first communication component 1512 may be dedicated to wireless communications, and a second communication component 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display device 1506 (or corresponding interface circuitry, as discussed above). The display device 1506 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any embedded or wired or wirelessly connected external device that generates an audible indicator, such speakers, headsets, or earbuds.

The electrical device 1500 may include an audio input device 1524 (or corresponding interface circuitry, as discussed above). The audio input device 1524 may include any embedded or wired or wirelessly connected device that generates a signal representative of a sound, such as microphones, microphone arrays, or digital instruments (e.g., instruments having a musical instrument digital interface (MIDI) output). The electrical device 1500 may include a Global Navigation Satellite System (GNSS) device 1518 (or corresponding interface circuitry, as discussed above), such as a Global Positioning System (GPS) device. The GNSS device 1518 may be in communication with a satellite-based system and may determine a geolocation of the electrical device 1500 based on information received from one or more GNSS satellites, as known in the art.

The electrical device 1500 may include another output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include another input device 1520 (or corresponding interface circuitry, as discussed above). Examples of the other input device 1520 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1500 may be any other electronic device that processes data. In some embodiments, the electrical device 1500 may comprise multiple discrete physical components. Given the range of devices that the electrical device 1500 can be manifested as in various embodiments, in some embodiments, the electrical device 1500 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is an apparatus, comprising: a glass layer having an upper surface and a lower surface, the glass layer comprising a plurality of through-glass vias (TGVs); a first dielectric layer comprising a first redistribution layer (RDL) located adjacent to the upper surface; a second dielectric layer comprising a second RDL located adjacent to the lower surface; at least one electrically communicative path from the first dielectric layer through a TGV to the second dielectric layer; a conductive layer located on a portion of the first dielectric layer; and a third RDL located on the conductive layer.

Example 2 includes the subject matter of Example 1, further comprising: a cavity wall located external to a periphery of the conductive layer, and a third dielectric layer located in the cavity wall.

Example 3 includes the subject matter of Example 1, wherein the conductive layer has a thickness of about 5 microns.

Example 4 includes the subject matter of Example 1, wherein the conductive layer has a thickness in a range of about 1 micron to about 10 microns.

Example 5 includes the subject matter of any one of Examples 1-4, wherein the conductive layer, the first RDL, the second RDL, and the third RDL comprise copper.

Example 6 includes the subject matter of any one of Examples 1-5, wherein the glass layer comprises silicon and oxygen.

Example 7 includes the subject matter of any one of Examples 1-5, wherein the glass layer comprises silicon, oxygen, and aluminum, boron, or an alkaline-earth metal.

Example 8 includes the subject matter of any one of Examples 1-7, wherein the glass layer has a thickness in a range of about 20 microns to about 2 millimeter.

Example 9 includes the subject matter of any one of Examples 1-7, wherein respective TGVs have a diameter of about 10 to about 150 microns.

Example 10 includes the subject matter of any one of Examples 1-8, further comprising a fourth dielectric layer located on the second dielectric layer.

Example 11 includes the subject matter of any one of Examples 1-10, further comprising, an embedded component located on the conductive layer and attached to the third RDL.

Example 12 includes the subject matter of Example 11 wherein the embedded component is attached to the third RDL via solder, and further comprising underfill between the embedded component and a cavity floor.

Example 13 includes the subject matter of Example 11, wherein the embedded component is a photonic integrated circuit (PIC).

Example 14 includes the subject matter of Example 11, wherein the embedded component is a silicon bridge.

Example 15 includes the subject matter of any one of Examples 1-14, wherein the third RDL located on the conductive layer is characterized by rounded walls.

Example 16 includes the subject matter of any one of Examples 1-14, wherein the third RDL located on the conductive layer is characterized by scalloped walls.

Example 17 includes the subject matter of any one of Examples 1-16, further comprising an epoxy layer between the glass layer and the second dielectric layer.

Example 18 is a substrate package comprising the subject matter of Example 1, and further comprising: an epoxy layer adjacent to the glass layer and located on the second dielectric layer.

Example 19 is a package assembly, comprising: an embedded component comprising a first side and a second side, and at least one electrically conductive path from the first side to the second side; and a substrate comprising: a glass layer having an upper surface and a lower surface, the glass layer comprising a plurality of through-glass vias (TGVs);
a first dielectric layer comprising a first redistribution layer (RDL) located adjacent to the upper surface; a second dielectric layer comprising a second RDL located adjacent to the lower surface; a conductive layer located on a portion of the first dielectric layer; a third RDL located on the conductive layer; a cavity wall comprising a third dielectric, the cavity wall encircling a periphery of the conductive layer, and
the embedded component located within the cavity wall, attached on the first side to the third RDL, and in electrical communication with an integrated circuit (IC) die on the second side.

Example 20 includes the subject matter of Example 19, wherein the embedded component is a photonic integrated circuit (PIC).

Example 21 includes the subject matter of Example 19, wherein the embedded component is a silicon bridge.

Example 22 includes the subject matter of Example 19, further comprising a printed circuit board (PCB), the PCB attached to the substrate.

Example X includes the subject matter of Example 19, further comprising a second IC die attached to the embedded component on the second side.

Example 23 includes the subject matter of Example 19, wherein the embedded component is attached to the third RDL via solder, and further comprising underfill between the embedded component and a cavity floor.

Example 24 is a method, comprising: fabricating a glass core with through-glass vias (TGVs), an upper surface, and a lower surface; locating a first redistribution layer (RDL) on the upper surface and lower surface; locating a layer of conductive material on a portion of the upper surface; patterning a second RDL over the conductive material; creating a dielectric cavity over the conductive material; performing a wet etch on the second RDL in the dielectric cavity; attaching a first side of an embedded component to the RDL in the dielectric cavity; and attaching an integrated circuit (IC) die to a second side of the embedded component.

Example 25 includes the subject matter of Example 24, further comprising building one or more additional layers of a dielectric material on the second RDL, and wherein creating the dielectric cavity comprises removing the dielectric material over the conductive material.

Example 26 includes the subject matter of Example 24, further comprising: attaching the first side of the embedded component to the RDL in the dielectric cavity via first solder bumps of a first solder material; and attaching the IC die to the second side of the embedded component via second solder bumps of a second solder material; and wherein the second solder material has a lower melting point than the first solder material.

Example 27 includes the subject matter of Example 24, further comprising putting underfill between the first side of the embedded component and the dielectric cavity.

Example 28 includes the subject matter of Example 24, further comprising creating an electrically conductive path from the second RDL through the embedded component to the IC die.

Example 29 is a device, comprising: an integrated circuit (IC) die; and a substrate including a glass core, the substrate comprising: a conductive layer overlaid on the glass core; a dielectric cavity having a redistribution layer (RDL) therein; the redistribution layer adjacent to the conductive layer; an embedded component comprising a first side, a second side, and at least one electrically conductive path from the first side to the second side, the embedded component located within the dielectric cavity, attached on the first side to the RDL, and in electrical communication with the IC die on the second side.

Example 30 includes the subject matter of Example 29, further comprising: a printed circuit board attached to the substrate.

Example 31 includes the subject matter of Example 30, further comprising: a heat spreader component attached to the IC die.

What is claimed is:

1. An apparatus, comprising:
a glass layer having an upper surface and a lower surface, the glass layer comprising a plurality of through-glass vias (TGVs);
a first dielectric layer comprising a first redistribution layer (RDL) located adjacent to the upper surface;
a second dielectric layer comprising a second RDL located adjacent to the lower surface;
at least one electrically communicative path from the first dielectric layer through a TGV to the second dielectric layer;
a conductive layer located on a portion of the first dielectric layer; and
a third RDL located on the conductive layer.

2. The apparatus of claim 1, further comprising:
a cavity wall located external to a periphery of the conductive layer, and
a third dielectric layer located in the cavity wall.

3. The apparatus of claim 1, wherein the conductive layer has a thickness of about 5 microns.

4. The apparatus of claim 1, wherein the conductive layer, the first RDL, the second RDL, and the third RDL comprise copper.

5. The apparatus of claim 1, wherein the glass layer comprises silicon and oxygen.

6. The apparatus of claim 1, wherein the glass layer has a thickness in a range of about 20 microns to about 2 millimeter.

7. The apparatus of claim 1, further comprising, an embedded component located on the conductive layer and attached to the third RDL.

8. The apparatus of claim 7 wherein the embedded component is attached to the third RDL via solder, and further comprising underfill between the embedded component and a cavity floor.

9. The apparatus of claim 7, wherein the embedded component is a photonic integrated circuit (PIC).

10. The apparatus of claim 7, wherein the embedded component is a silicon bridge.

11. The apparatus of claim 1, wherein the third RDL located on the conductive layer is characterized by rounded walls.

12. The apparatus of claim 1, wherein the third RDL located on the conductive layer is characterized by scalloped walls.

13. The apparatus of claim 1, further comprising an epoxy layer between the glass layer and the second dielectric layer.

14. A substrate package comprising the apparatus of claim 1, and further comprising:
an epoxy layer adjacent to the glass layer and located on the second dielectric layer.

15. A package assembly, comprising:
an embedded component comprising a first side and a second side, and at least one electrically conductive path from the first side to the second side; and
a substrate comprising:
a glass layer having an upper surface and a lower surface, the glass layer comprising a plurality of through-glass vias (TGVs);
a first dielectric layer comprising a first redistribution layer (RDL) located adjacent to the upper surface;
a second dielectric layer comprising a second RDL located adjacent to the lower surface;
a conductive layer located on a portion of the first dielectric layer;
a third RDL located on the conductive layer;
a cavity wall comprising a third dielectric, the cavity wall encircling a periphery of the conductive layer, and
the embedded component located within the cavity wall, attached on the first side to the third RDL, and in electrical communication with an integrated circuit (IC) die on the second side.

16. The package assembly of claim 15, wherein the embedded component is a photonic integrated circuit (PIC).

17. The package assembly of claim 15, wherein the embedded component is a silicon bridge.

18. The package assembly of claim 15, further comprising a printed circuit board (PCB), the PCB attached to the substrate.

19. The package assembly of claim 15, further comprising a second IC die attached to the embedded component on the second side.

20. The package assembly of claim 15, wherein the embedded component is attached to the third RDL via solder, and further comprising underfill between the embedded component and a cavity floor.

21. A method, comprising:
fabricating a glass core with through-glass vias (TGVs), an upper surface, and a lower surface;
locating a first redistribution layer (RDL) on the upper surface and lower surface;
locating a layer of conductive material on a portion of the upper surface;
patterning a second RDL over the conductive material;
creating a dielectric cavity over the conductive material;
performing a wet etch on the second RDL in the dielectric cavity;
attaching a first side of an embedded component to the RDL in the dielectric cavity; and
attaching an integrated circuit (IC) die to a second side of the embedded component.

22. The method of claim 21, further comprising building one or more additional layers of a dielectric material on the second RDL, and wherein creating the dielectric cavity comprises removing the dielectric material over the conductive material.

23. The method of claim 21, further comprising:
attaching the first side of the embedded component to the RDL in the dielectric cavity via first solder bumps of a first solder material; and
attaching the IC die to the second side of the embedded component via second solder bumps of a second solder material; and
wherein the second solder material has a lower melting point than the first solder material.

24. The method of claim 21, further comprising creating an electrically conductive path from the second RDL through the embedded component to the IC die.

25. A device, comprising:
an integrated circuit (IC) die; and
a substrate including a glass core, the substrate comprising:
a conductive layer overlaid on the glass core;
a dielectric cavity having a redistribution layer (RDL) therein;
the redistribution layer adjacent to the conductive layer;
an embedded component comprising a first side, a second side, and at least one electrically conductive path from the first side to the second side, the embedded component located within the dielectric cavity, attached on the first side to the RDL, and in electrical communication with the IC die on the second side; and
a printed circuit board attached to the substrate.
